(19) United States
(12) Patent Application Publication
(10) Pub. No.: US 2024/0168101 A1
(43) Pub. Date: May 23, 2024

(54) METHOD FOR ESTIMATING STATE OF HEALTH OF LITHIUM-SULFUR BATTERY

(71) Applicant: LG ENERGY SOLUTION, LTD., Seoul (KR)

(72) Inventors: Jihoon AHN, Daejeon (KR); Bong Soo KIM, Daejeon (KR); Dong Hyeop HAN, Daejeon (KR)

(21) Appl. No.: 18/282,501

(22) PCT Filed: Nov. 21, 2022
(86) PCT No.: PCT/KR2022/018402

§ 371 Date: Sep. 15, 2023

(30) Foreign Application Priority Data
Nov. 22, 2021 (KR) 10-2021-0160919

(51) Int. Cl. G01R 31/392; G01R 31/36; G01R 31/378; G01R 31/3835; H01M 10/052

(52) U.S. Cl. CPC G01R 31/392; G01R 31/3648; G01R 31/378; G01R 31/3835; H01M 10/052

(57) ABSTRACT

A method of estimating a state of health (SoH) of a lithium-sulfur battery is provided. The method includes a) maintaining a target battery for estimating the state of health in a rest state for 0.01 seconds or more in a state in which the target battery is fully charged; b) measuring OCV_{(det)} in a state in which a voltage drop is made during the rest state; c) calculating ΔOCV by subtracting OCV_{(det)} from OCV₍ᵢₙᵢ₎ previously measured in the same manner as in steps a) and b) at an initial stage of use of the target battery; and d) estimating a state of health (%) of the battery from a magnitude of the ΔOCV.

### CROSS-REFERENCE TO RELATED APPLICATION(S)

This application is a National Stage Application of International Application No. PCT/KR2022/018402, filed on Nov. 21, 2022, which claims the benefit of priority based on Korean Patent Application No. 10-2021-0160919 filed on Nov. 22, 2021, the disclosures of which are incorporated herein by reference in their entirety.

### FIELD OF DISCLOSURE

The present disclosure relates to a method of estimating a state of health of a lithium-sulfur battery.

### BACKGROUND

Recently, as mobile electronic devices, electric vehicles, and large-capacity power storage systems, and the like develop, the need for large-capacity batteries is rising up. Lithium-sulfur batteries are secondary batteries that use a sulfur-based material having a sulfur-sulfur bond (S—S bond) as a cathode active material and use a lithium metal as an anode active material, and sulfur, which is a main material of the cathode active material, has advantages in that it is very abundant in resources, non-toxic, and has a low weight per atom.

A theoretical discharging capacity of the lithium-sulfur batteries is 1672 mAh/g-sulfur, and a theoretical energy density of the lithium-sulfur batteries is 2,600 Wh/kg, which is very high compared to theoretical energy densities of other battery systems that are currently being studied. Therefore, the lithium-sulfur batteries have attracted attention as batteries having high energy density characteristics.

A typical lithium-sulfur battery includes an anode formed of a lithium metal or a lithium metal alloy and a cathode formed of elemental sulfur or other electroactive sulfur materials.

The sulfur at the cathode of the lithium-sulfur battery is reduced in two steps when the lithium-sulfur battery is discharged. In a first step, sulfur (e.g. the elemental sulfur) is reduced to lithium polysulfide (Li₂S₈, Li₂S₆, Li₂S₅, or Li₂S₄). These species are generally dissolved in an electrolyte solution. In a second step, the lithium polysulfide is reduced to Li₂S that may be deposited on a surface of the anode. Conversely, when the lithium-sulfide battery is charged, Li₂S is oxidized to lithium polysulfide (Li₂S₈, Li₂S₆, Li₂S₅, or Li₂S₄), and then oxidized to lithium and sulfur.

Like a general battery, the lithium-sulfur battery is gradually deteriorated as it is repeatedly charged and discharged. Even though the deteriorated battery is fully charged up to a voltage limit, a usable capacity is smaller than an initial usable capacity, and a ratio of a current usable capacity to the initial usable capacity may be expressed as a state of health.

The state of health may be theoretically calculated by the following Equation.

SoH %=[C_{(det)}/C₍ᵢₙᵢ₎]×100

Here, C_{(det)} refers to a usable capacity of the battery after being deteriorated, and C₍ᵢₙᵢ₎ refers to an initial usable capacity of the battery (usable capacity of the before being deteriorated)

Such state of health (SoH) information of the battery enables a user to establish an appropriate battery use plan, and accordingly, enables improvement of use efficiency, reliability, and safety of the battery.

Meanwhile, the C_{(det)} may be calculated by completely discharging a buffered battery and measuring a quantity of electric charge, but since there are not many situations in which the battery is fully charged and completely discharged in an actual use environment of the battery, it is not practical to estimate the SoH by the above-described method.

Therefore, the development of a method capable of practically and reliably estimating the SoH has been required. In particular, the lithium-sulfur battery has a chemical behavior different from that of other lithium ion batteries, and thus, the development of a method of estimating a SoH of the lithium-sulfur battery appropriate for such characteristics has been required.

### RELATED ART

Japanese Patent Laid-Open Publication No. 2005-172784

### SUMMARY

The present disclosure is devised to solve the above problems in the related art, and it is an object of the present disclosure to provide a method of estimating a state of health (SoH) of a lithium-sulfur battery capable of quickly and reliably estimating the state of health of the lithium-sulfur battery in a simple manner.

It is another object of the present disclosure to provide a method of estimating a state of health of a lithium-sulfur battery that can be practically used.

In order to achieve the above objects,
the present disclosure is a method of confirming a deterioration state of the lithium-sulfur battery, and
provides a method of estimating a state of health (SoH) of a lithium-sulfur battery, including the steps of:
a) maintaining a target battery for estimating the state of health in a rest state for 0.01 seconds or more in a state in which the target battery is fully charged;
b) measuring OCV_{(det)} in a state in which a voltage drop is made during the rest state;
c) calculating ΔOCV by subtracting OCV_{(det)} from OCV₍ᵢₙᵢ₎ previously measured in the same manner as in steps a) and b) at an initial stage of use of the target battery; and
d) estimating a state of health (%) of the battery from a magnitude of ΔOCV.

With the method of estimating a state of health (SoH) of a lithium-sulfur battery of the present disclosure, a method of quickly and reliably estimating the state of health of the lithium-sulfur battery in a simple manner is provided.

In addition, a method estimating a state of health of a lithium-sulfur battery capable of being practically used is provided.

### DESCRIPTION OF DRAWINGS

FIG. 1 is graphs showing the voltage drops during a rest period after full charging of a fresh lithium-sulfur battery and a deteriorated lithium-sulfur battery.

FIG. 2 is graphs obtained by obtaining state of health (%) (SoH (%)) data of a lithium-sulfur battery in each charging/discharging cycle while repeatedly fully charging and fully discharging the lithium-sulfur battery and β data at a predetermined point in time during a rest period after charging of the lithium-sulfur battery, showing SoH (%) on a y-axis and showing β on an x-axis, and fitting the data obtained above with a specific function.
(β: OCV obtained by subtracting OCV_{(det)} measured at a predetermined point in time during a rest period after full charging of the lithium-sulfur battery in each cycle from OCV₍ᵢₙᵢ₎ measured at a predetermined point in time during the rest period after full charging of the battery when charging of the battery in an initial cycle)

FIG. 3 is a flowchart showing a method of estimating a state of health according to the present disclosure.

### DETAILED DESCRIPTION

Hereinafter, preferred embodiments of the present disclosure will be described in detail with reference to the accompanying drawings. Prior to describing the present disclosure, in the case where it is determined that the detailed description of well-known constructions or functions may unnecessarily obscure the gist of the present disclosure, the description thereof will be omitted.

The following description and drawings illustrate specific embodiments to enable those skilled in the art to easily practice a device and method to be described. Other embodiments may include other structural and logical modifications. Individual components and functions may be generally selected unless expressly required, and the order of processes may change. Portions and features of some embodiments may be included in or substituted for other embodiments.

When a lithium-sulfur battery is charged up to an upper limit voltage and thus charging ends, and enters a rest period, a voltage drop occurs. Such a voltage drop is understood as a self-discharging phenomenon caused by a polysulfide shuttle phenomenon unique to the lithium-sulfur battery along with the resolution of charging overvoltage.

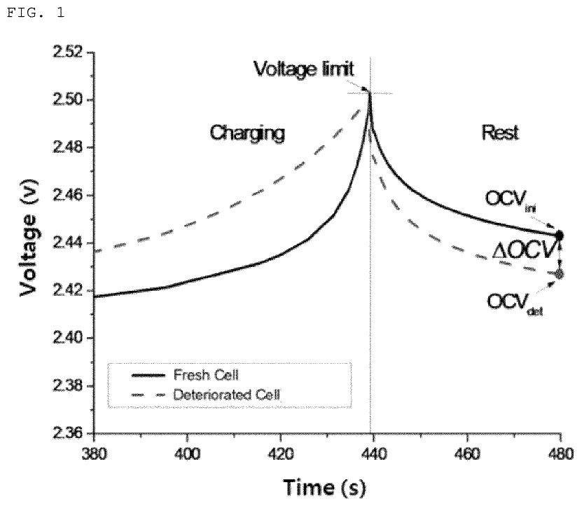

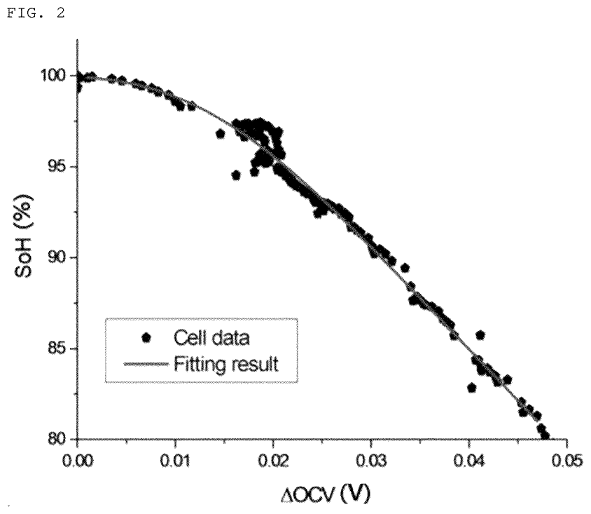

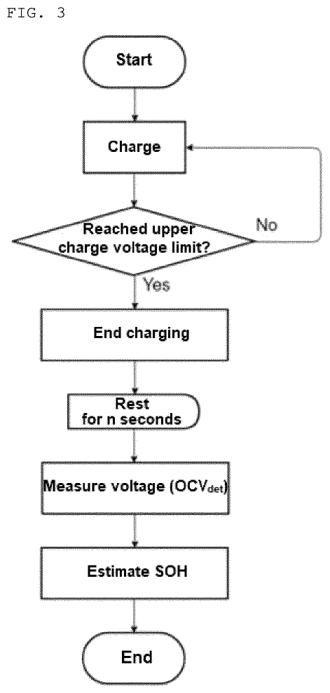

As shown in FIG. 1, in the case of a deteriorated battery, as deterioration of the battery progresses, a voltage drop phenomenon appears greater as compared with a fresh battery, and such a phenomenon results from a cause in which a battery resistance is increased due to the deterioration of electrodes and an electrolyte and thus a charging overvoltage is increased, and a cause in which a polysulfide shuttle phenomenon is intensified due to electrolyte deterioration. Therefore, a voltage drop in the rest period after charging of the battery is determined by data providing information on the deterioration of the battery.

The present inventors have completed the present disclosure using a magnitude (ΔOCV) of the voltage drop in the rest period after charging of the battery as an estimation parameter for a state of health (SoH) of the battery according to the research results as described above.

In the present disclosure, the state of health of the battery may also be expressed as a deterioration state of the battery.

Hereinafter, the present disclosure will be described in detail.

The present disclosure is a method of confirming a deterioration state of the lithium-sulfur battery, and
provides a method of estimating a state of health (SoH) of a lithium-sulfur battery, including the steps of:
a) maintaining a target battery for estimating the state of health in a rest state for 0.01 seconds or more in a state in which the target battery is fully charged;
b) measuring OCV_{(det)} in a state in which a voltage drop is made during the rest state;
c) calculating ΔOCV by subtracting OCV_{(det)} from OCV₍ᵢₙᵢ₎ previously measured in the same manner as in steps a) and b) at an initial stage of use of the target battery; and
d) estimating a state of health (%) of the battery from a magnitude of the ΔOCV.

In the present disclosure, OCV is an acronym of an Open Circuit Voltage, and refers to an open circuit voltage of the battery.

FIG. 2 is graphs obtained by obtaining state of health (%) (SoH (%)) data of a lithium-sulfur battery in each charging/discharging cycle while repeatedly fully charging and fully discharging the lithium-sulfur battery and β data at a predetermined point in time during a rest period after charging of the lithium-sulfur battery and showing SoH (%) on a y-axis and showing β on an x-axis.

As can be seen from FIG. 2, as the deterioration of the battery progresses, since a value of the ΔOCV gradually increases and a magnitude of the value of ΔOCV has a negative correlation with SoH (%), from such a relationship, it is possible to estimate the state of health of the battery from the ΔOCV.

In the present disclosure, the state of health (%) refers to State of Health (SoH) (%), and also refers to a deterioration state (%) in another meaning. In addition, in the present disclosure, the OCV refers to an Open Circuit Voltage.

In an embodiment of the present disclosure, the estimating of the state of health (%) of the battery in step d) may be performed using a negative correlation function between the state of health (%) of the lithium-sulfur battery and the magnitude of ΔOCV. The negative correlation function refers to, for example, a function expressing a relationship in which a value of SoH (%) becomes smaller as ΔOCV increases in a relationship between SoH (%) and ΔOCV.

The negative correlation function may be expressed as SoH (%)=f(ΔOCV).

In an embodiment of the present disclosure, the estimating of the state of health (%) of the battery in step d) may be performed by a method of comparing the measured ΔOCV with a state of health (%) mapping reference of the battery prepared in advance and corresponding to the magnitude of ΔOCV.

In an embodiment of the present disclosure, the state of health (%) mapping reference of the battery corresponding to the magnitude of ΔOCV may be data created by repeating full charging and full discharging of a battery manufactured in the same manner as the target battery for estimating the state of health to obtain state of health (%) (SoH (%)) data of the battery according to Equation 1 in each charging/discharging cycle, obtaining ΔOCV data in the same manner as above, and matching these data in a one-to-one manner.

SoH (%)=[C_{(det)}/C₍ᵢₙᵢ₎]×100 [Equation 1]

C₍ᵢₙᵢ₎: usable capacity before deterioration, C_{(det)}: usable capacity after deterioration

Wherein, the usable capacity may be obtained by completely discharging the fully charged battery and measuring a quantity of electric charge, as known in the art. Specifically, for example, the usable capacity of the battery before deterioration and the usable capacity of the battery after deterioration may be calculated by repeatedly performing a cycle of applying a current having a magnitude of 0.2 C to the battery so that a battery voltage becomes 2.5V to charge the battery, discharging the battery with a current having a magnitude of 0.3 C until the battery voltage reaches 1.8V, and measuring a quantity of electric charge obtained when discharging the battery. However, the usable capacity is not limited to this method, and may be calculated using a method known in the art.

In an embodiment of the present disclosure, the state of health mapping reference may be, for example, a graph showing SoH (%) on the y-axis and the magnitude of ΔOCV on the x-axis, or a lookup table in which SoH (%) and the magnitude of ΔOCV corresponding to SoH (%) are matched in a one-to-one manner.

In an embodiment of the present disclosure, a rest state maintaining period in step a) may be 0.01 second or more, preferably 0.05 second or more, and more preferably 0.1 second or more. When the rest state maintaining period is less than 0.01 second, it may be difficult to estimate the state of health (%) of the battery due to a small difference in the magnitude of ΔOCV according to the deterioration state of the battery, and the accuracy of estimation may also be decreased.

The rest state maintaining period may be 0.01 second to 3 minutes, preferably 0.01 second to 2 minutes, more preferably 0.01 second to 1 minute, and even more preferably 0.01 second to 30 seconds. When the rest state maintaining period exceeds 3 minutes, it is not preferable because it takes too long time to estimate SoH (%) and it is difficult to estimate SoH (%) in real time.

In an embodiment of the present disclosure, the initial stage in step c) may be from the first use of the battery to a timepoint when a deterioration rate of the battery is within 10%, preferably from a first use of the battery to a point in time when a deterioration rate of the battery is within 5%, 3%, or 1%, and more preferably a first use point in time of the battery.

In an embodiment of the present disclosure, the estimating of the state of health (%) of the battery from the magnitude of ΔOCV in step d) may be performed by a method of obtaining a scatter plot graph using state of health (%) data of a battery obtained in each cycle by repeating full charging and full discharging for the battery manufactured in the same manner as the target battery for estimating the state of health as a y-axis value and using ΔOCV data obtained in the same manner as the above as an x-axis value, obtaining a fitting function by applying the least squares method to the scatter plot graph, and substituting ΔOCV obtained from the target battery into the fitting function.

In an embodiment of the present disclosure, the estimating of the state of health (%) of the battery from the magnitude of ΔOCV in step d) may be performed by the following Equation 2:

$$SoH ( \% ) = {\sum }_{i = 1}^{j} [ {{a}_{i} ( {OCV}_{( ini )} - {OCV}_{( det )} )}^{i} ] + C . \qquad [ Equation 2 ]$$

wherein,
OCV₍ᵢₙᵢ₎ is OCV measured after the battery is maintained in the rest state for 0.01 seconds or more in the state in which the battery is fully charged at the initial stage of the use of the battery,
OCV_{(det)} is OCV measured after the target battery for estimating the state of health is maintained in the rest state for the same period as the rest state maintaining period in the state in which the target battery is fully charged,
j is the highest dimension of a polynomial function,
aᵢ is a coefficient of an i-th order term, and c is a value of SoH (%) corresponding to OCV₍ᵢₙᵢ₎.

Wherein, j may be 2 to 10, and preferably 3 to 5.

Wherein, aᵢ and c may be changed depending on various design factors of a cell, but it may be assumed that aᵢ and c have the same values for the same design. Accordingly, when the aᵢ and c are obtained through an experiment on the manufactured battery, the state of health (%) of the battery may be very simply and reliably estimated by calculating ΔOCV of the target battery.

The aᵢ is a coefficient of each order term in a polynomial function having an arbitrarily set highest order term j by applying the least squares method to the scatter plot graph plotted using the state of health (%) data of the battery obtained in each cycle by repeating full charging and full discharging for the battery manufactured in the same manner as the target battery for estimating the state of health as the y-axis value and using the ΔOCV data obtained in the same manner as the above as the x-axis value and. The least squares method is a method well known to those skilled in the art.

In the above, j may be arbitrarily set in the range of 2 to 10 and preferably 3 to 5 so that an adjusted R-squared (Adj. R²) after fitting has a value of 0.90 or more, preferably 0.95 or more, and more preferably 0.98 or more.

Equation 2 may be expressed as Equation 3.

$$SoH ( \% ) = {\sum }_{i = 1}^{j} ( {a}_{i} \times Δ {OCV}^{i} ) + C \qquad [ Equation 3 ]$$

FIG. 3 is a flowchart showing a method of estimating a state of health of a lithium-sulfur battery according to the present disclosure. According to the present disclosure, the state of health of the battery may be practically and reliably provided by a simple method as shown in FIG. 3.

### EXAMPLES

Hereinafter, preferred examples will be provided in order to help understand the present disclosure. However, it will be obvious to those skilled in the art that the following Examples are only an example of the present disclosure and various modifications and alterations may be made without departing from the scope and spirit of the present disclosure. In addition, it is natural that these modifications and alterations will fall within the appended claims.

### Example 1: Estimation of State of Health of Lithium-Sulfur Battery

State of health (%) (SoH (%)) data and ΔOCV data of a lithium-sulfur battery in each charging/discharging cycle were obtained while repeating full charging and full discharging of the lithium-sulfur battery that was not used.

Specifically, the SoH (%) data in each cycle was obtained by the following Equation 1:

SoH (%)=[C_{(det)}/C₍ᵢₙᵢ₎]×100 [Equation 1]

C₍ᵢₙᵢ₎: usable capacity of the battery before deterioration, and C_{(det)}: usable capacity of the battery after deterioration.

Specifically, the SoH (%) data was obtained by calculating the usable capacity of the battery before being deteriorated and the usable capacity of the battery after being deteriorated by repeatedly performing a cycle of applying a current having a magnitude of 0.2 C to the battery so that a battery voltage becomes 2.5V to charge the battery, discharging the battery with a current having a magnitude of 0.3 C until the battery voltage reaches 1.8V, and measuring a quantity of electric charge obtained when discharging the battery.

In addition, the ΔOCV data was obtained by first fully charging the battery in a first cycle, maintaining the battery in a rest state for 10 seconds, measuring OCV in a state in which a voltage drop is made to obtain OCV₍ᵢₙᵢ₎, and thereafter fully charging the battery in each cycle, maintaining the battery in a rest state for 10 seconds, measuring each OCV in a state in which a voltage drop is made to obtain each OCV_{(det)}, and then subtracting each OCV_{(det)} from OCV₍ᵢₙᵢ₎ to calculate ΔOCV in each cycle.

As a result of showing the SoH (%) data obtained in each cycle on the y-axis and showing ΔOCV on the x-axis, the scatter plot graph as shown in FIG. 2 was obtained. It can be seen from the graph of FIG. 2 that a magnitude of a value of ΔOCV has a negative correlation with a value of SoH (%) and such a graph may be used as a mapping reference for a target battery for estimating the state of health in comparison to ΔOCV of the target battery measured at a predetermined point in time.

Therefore, if using such a mapping reference, when ΔOCV of the target battery at a predetermined point in time is calculated, the SoH (%) may be easily calculated by comparing a value of the ΔOCV with the mapping reference.

### Example 2: Estimation of State of Health of Lithium-Sulfur Battery

A ΔOCV function for SoH (%) corresponding to the graph of FIG. 2 obtained in Example 1 was designed as follows.

$$SoH ( \% ) = {\sum }_{i = 1}^{j} [ {{a}_{i} ( {OCV}_{( ini )} - {OCV}_{( det )} )}^{i} ] + C . \qquad [ Equation 2 ]$$

Wherein,
OCV₍ᵢₙᵢ₎ is OCV measured after the battery is maintained in a rest state for 0.01 second or more in a first cycle,
OCV_{(det)} is OCV measured after a target battery for estimating the state of health is maintained in a rest state for 10 seconds in a state in which the target battery is fully charged,
j is the highest dimension of a polynomial function,
aᵢ is a coefficient of an i-th order term, and
c is a value of SoH (%) corresponding to OCV₍ᵢₙᵢ₎.

In the function, aᵢ is a coefficient of each order term in a polynomial function having an arbitrarily set highest order term j by applying the least squares method to a scatter plot of Example 1, and it was confirmed that the polynomial function fitted as such was fitted to the scatter plot graph obtained in Example 1 in a state in which it has a very high adjusted R-squared (Adj. R²=0.983), as illustrated in FIG. 2.

In the above, aᵢ and c may be changed depending on various design factors of a cell, but it may be assumed that aᵢ and c have the same values for the same design.

Therefore, it can be seen from the fitting result that when the function of Equation 2 is used, SoH (%) may be very simply obtained by obtaining ΔOCV at a predetermined point in time for the target battery.

1. A method of estimating a state of health (SoH) of a lithium-sulfur battery, the method comprising:
a) maintaining a rest state for 0.01 seconds or more in a state in which a target battery for estimating the state of health is fully charged;
b) measuring OCV_{(det)} in a state in which a voltage drop is made during the rest state;
c) calculating ΔOCV by subtracting the OCV_{(det)} from OCV₍ᵢₙᵢ₎ previously measured in the same manner as in steps a) and b) at an initial stage of use of the target battery; and
d) estimating a state of health (%) of the battery from a magnitude of the ΔOCV.

2. The method according to claim 1, wherein the estimating of the state of health (%) of the battery in step d) is performed using a negative correlation function between the state of health (%) of the lithium-sulfur battery and the magnitude of ΔOCV.

3. The method according to claim 1, wherein the estimating of the state of health (%) of the battery in step d) is performed by a method of comparing the measured ΔOCV with a state of health (%) mapping reference of the battery prepared in advance and corresponding to the magnitude of ΔOCV.

4. The method according to claim 3, wherein the state of health (%) mapping reference of the battery corresponding to the magnitude of ΔOCV is data created by repeating full charging and full discharging of a battery manufactured in the same manner as the target battery for estimating the state of health to obtain state of health (%) (SoH (%)) data of the battery according to Equation 1 in each charging/discharging cycle, obtaining ΔOCV data in the same manner as the above manner, and matching these data to each other in a one-to-one manner,
SoH (%)=[C_{(det)}/C₍ᵢₙᵢ₎]×100 [Equation 1]
wherein C₍ᵢₙᵢ₎ refers to a usable capacity of the battery before being deteriorated, and C_{(det)} refers to a usable capacity of the battery after being deteriorated.

5. The method according to claim 4, wherein the state of health mapping reference is a graph showing SoH (%) on a y-axis and the magnitude of ΔOCV on an x-axis or a lookup table in which SoH (%) and the magnitude of ΔOCV corresponding to SoH (%) are matched to each other in a one-to-one manner.

6. The method according to claim 1, wherein the “initial stage” in step c) is from the first use of the battery to a timepoint when a deterioration rate of the battery is within 10%.

7. The method according to claim 1, wherein the estimating of the state of health (%) of the battery from the magnitude of ΔOCV in step d) is performed by a method of obtaining a scatter plot graph using state of health (%) data of a battery obtained in each cycle by repeating full charging and full discharging for the battery manufactured in the same manner as the target battery for estimating the state of health as a y-axis value and using ΔOCV data obtained in the same manner as the above manner as an x-axis value, obtaining a fitting function by applying the least squares method to the scatter plot graph, and substituting ΔOCV obtained from the state of health confirmation target battery into the fitting function.

8. The method according to claim 1, wherein the estimating of the state of health (%) of the battery from the magnitude of ΔOCV in step d) is performed by the following Equation 2:
$$SoH ( \% ) = {\sum }_{i = 1}^{j} [ {{a}_{i} ( {OCV}_{( ini )} - {OCV}_{( det )} )}^{i} ] + C . \qquad [ Equation 2 ]$$
wherein,
OCV₍ᵢₙᵢ₎ is OCV measured after the battery is maintained in the rest state for 0.01 seconds or more in the state in which the battery is fully charged at the initial stage of the use of the battery,
the OCV_{(det)} is OCV measured after the target battery is maintained in the rest state for the same period as the rest state maintaining period in the state in which the target battery is fully charged,
j is the highest dimension of a polynomial function,
aᵢ is a coefficient of an i-th order term, and
c is a value of SoH (%) corresponding to OCV₍ᵢₙᵢ₎.

9. The method according to claim 1, the rest state in step a) is maintained for 0.01 seconds to 3 minutes.
